(19) United States
(12) Patent Application Publication
(10) Pub. No.: US 2016/0286680 A1
(43) Pub. Date: Sep. 29, 2016

(54) SERVER RACK

(71) Applicant: NATIONAL CHIAO TUNG UNIVERSITY, Hsinchu City (TW)

(72) Inventors: Yeng-Yung TSUI, Hsinchu City (TW); Chi-Chuan WANG, Hsinchu County (TW); I-Nuo WANG, New Taipei City (TW)

(21) Appl. No.: 14/711,749

(22) Filed: May 13, 2015

(30) Foreign Application Priority Data
Mar. 23, 2015 (TW) 104109213

(51) Int. Cl. H05K 7/14; H05K 7/20

(52) U.S. Cl. CPC H05K 7/1489; H05K 7/20736

(57) ABSTRACT

A server rack includes a frame, servers and slide rail structures. The frame has a bottom end and a top end opposite to each other. The servers are stacked between the bottom end and the top end. Each of the servers has an operation end and a heat-dissipation end opposite to each other. The slide rail structures connect the servers to the frame for allowing each of the servers to at least partially slide out of the frame towards the corresponding operation end. A distance by which each of the servers slides out of the frame is greater than or equal to a distance by which the adjacent server located closer to the bottom end slides out of the frame.

### RELATED APPLICATIONS

This application claims priority to Taiwanese Application Serial Number 104109213, filed Mar. 23, 2015, which is herein incorporated by reference.

### BACKGROUND

1. Technical Field

The present disclosure relates to a server rack.

2. Description of Related Art

With the advancement of technology, Internet has become one of the most major media of information exchange in our daily lives. In order to provide diversified Internet services, a server is essential equipment. A host computer can access the information in the server through the Internet, leading to a rapid transmission of information. When a large amount of information is to be accessed, a server rack is disposed in a computer system for accommodating sufficient servers.

In general, for the sake of easy management, the server racks is disposed in a chamber such as a server room or a data center, in which the temperature adjustment is emphasized. However, when the servers operate, the heat produced by the servers will increase the temperature in the chamber. Thus, the heat-dissipation of the servers is affected, and the servers may be damaged due to overheat.

As a result, the method for increasing the heat-dissipation of the chamber accommodating the server rack and maintaining a proper temperature of the chamber, is an important direction of development of the industry.

### SUMMARY

A technical aspect of the present disclosure is to provide a server rack, which can increase the heat-dissipation of the servers received therein, facilitate energy saving and reduce the chance of forming a local hot spot in the chamber.

According to an embodiment of the present disclosure, a server rack includes a frame, servers and slide rail structures. The frame has a bottom end and a top end opposite to each other. The servers are stacked between the bottom end and the top end. Each of the servers has an operation end and a heat-dissipation end opposite to each other. The slide rail structures connect the servers to the frame for allowing each of the servers to at least partially slide out of the frame towards the corresponding operation end. A distance by which each of the servers slides out of the frame is greater than or equal to a distance by which the adjacent server located closer to the bottom end slides out of the frame.

In one or more embodiments of the present disclosure, each of the slide rail structures includes a pair of inner rails and a pair or outer rails. The pair of inner rails is respectively connected to two opposite sides of the corresponding server. The pair or outer rails is respectively connected to the corresponding pair of inner rails and connected to the frame. The corresponding pair of inner rails is slidable relative to the pair of the outer rails.

In one or more embodiments of the present disclosure, each of the slide rail structures further includes a locking portion configured to fix a relative position between the corresponding pair of inner rails and the corresponding pair of outer rails.

In one or more embodiments of the present disclosure, the servers slide along a first direction.

In one or more embodiments of the present disclosure, the servers are arranged along a second direction. The second direction and the first direction are substantially perpendicular to each other.

In one or more embodiments of the present disclosure, each of the servers includes a fan located at the corresponding heat-dissipation end.

When being compared with the prior art, the embodiments of the present disclosure mentioned above have at least the following advantages:
(1) The space of the hot aisle close to the top end is increased to facilitate the hot air produced during the operation of the servers to flow towards a ventilation fan. Consequently, the chance of the hot air flowing into the cold aisle is reduced, such that the heat-dissipation of the servers is correspondingly increased, thus facilitating energy saving and reducing the chance of forming a local hot spot in the chamber.

(2) Since the space of the cold aisle close to the top end is decreased, the hot air produced during the operation of the servers can be prevented from rising up from the hot aisle to the top of the server rack and then flowing towards the cold aisle. Therefore, sufficient cold air in the cold aisle can be maintained, thus further facilitating energy saving and reducing the chance of forming a local hot spot in the chamber.

(3) The pair of inner rails is respectively connected to two opposite sides of the corresponding server, and the pair or outer rails is respectively connected to the corresponding pair of inner rails and connected to the frame. The corresponding pair of inner rails is slidable relative to the pair of the outer rails. Through this simple structure, a user can briefly slide each of the servers out of the frame without using any extra tools. Thus, the user can adjust the size of the spaces of the cold aisle and the hot aisle conveniently, thereby meeting the heat-dissipation requirements of the servers.

### BRIEF DESCRIPTION OF THE DRAWINGS

The disclosure can be more fully understood by reading the following detailed description of the embodiments, with reference made to the accompanying drawings as follows:

FIG. 1 is a schematic application diagram of a server rack according to an embodiment of the present disclosure; and

FIG. 2 is a schematic application diagram of a server rack according to another embodiment of the present disclosure.

### DETAILED DESCRIPTION

Drawings will be used below to disclose a plurality of embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

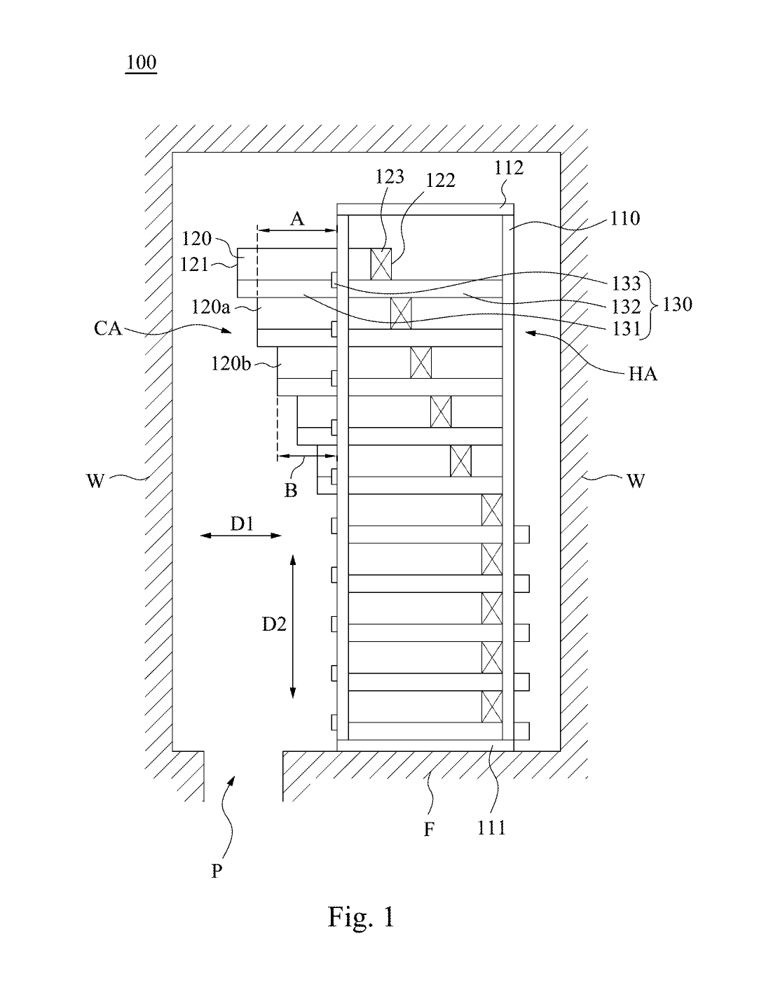

Please refer to FIG. 1. FIG. 1 is a schematic application diagram of a server rack 100 according to an embodiment of the present disclosure. As shown in FIG. 1, the server rack 100 includes a frame 110, servers 120 and slide rail structures 130. The frame 110 has a bottom end 111 and a top end 112 opposite to each other. The servers 120 are stacked between the bottom end 111 and the top end 112. Each of the servers 120 has an operation end 121 and a heat-dissipation end 122 opposite to each other. The slide rail structures 130 connect the servers 120 to the frame 110 for allowing each of the servers 120 to at least partially slide out of the frame 110 towards the corresponding operation end 121. A distance by which each of the servers 120 slides out of the frame 110 is greater than or equal to a distance by which the adjacent server 120 located closer to the bottom end 111 slides out of the frame 110. In practical applications, the server rack 100 can be disposed on top of other server rack, or directly disposed on the ground for use. However, this does not intend to limit the present disclosure.

In this embodiment, the servers 120 are arranged along a second direction D2 between the bottom end 111 and the top end 112, while the servers 120 slide along a first direction D1. In this embodiment, the second direction D2 and the first direction D1 are substantially perpendicular to each other. However, this does not intend to limit the present disclosure.

In general, the server rack 100 is utilized in a chamber such as a server room or a data center, in which the temperature adjustment is emphasized. As shown in FIG. 1, the server rack 100 is located between two sidewalls W of the chamber. For example, the heat-dissipation end 122 of each of the servers 120 faces the right hand side of FIG. 1, while the operation end 121 of each of the servers 120 faces the left hand side of FIG. 1. When the servers 120 operate, heat is emitted from the heat-dissipation ends 122 and hot air is produced. Thus, a hot aisle HA is formed between the servers 120 and the sidewall W at the right hand side of FIG. 1. In contrast, a cold aisle CA is formed between the servers 120 and the sidewall W at the left hand side of FIG. 1. In practical applications, each of the servers 120 includes a fan 123. The fan 123 is located at the corresponding heat-dissipation end 122, so as to increase the heat-dissipation of the servers 120.

Furthermore, as mentioned above, the distance by which each of the servers 120 slides out of the frame 110 is greater than or equal to the distance by which the adjacent server 120 located closer to the bottom end 111 slides out of the frame 110. Therefore, in contrast, the servers 120 closer to the top end 112 are relatively closer to the sidewall W at the left hand side of FIG. 1, while the servers 120 closer to the bottom end 111 are relatively farther away from the sidewall W at the left hand side of FIG. 1.

For the sake of clarity, two adjacent servers 120 of FIG. 1 are respectively marked as 120a and 120b. The server 120b is located closer to the bottom end 111 of the frame 110 than the server 120a is. The distance A by which the server 120a slides out of the frame 110 is greater than the distance B by which the server 120b slide out of the frame 110. Therefore, the server 120a is located closer to the sidewall W at the left hand side of FIG. 1 than the server 120b is.

Since the servers 120 located closer to the top end 112 are relatively closer to the sidewall W at the left hand side of FIG. 1, while the servers 120 located closer to the bottom end 111 are relatively farther away from the sidewall W at the left hand side of FIG. 1, the space of the cold aisle CA close to the top end 112 is decreased, while in contrast the space of the hot aisle HA close to the top end 112 is increased.

In details, the increase of the space of the hot aisle HA close to the top end 112 can facilitate the hot air produced during the operation of the servers 120 to flow towards a ventilation fan (not shown). In general, the flowing direction of the hot air towards the ventilation fan enters FIG. 1 or leaves FIG. 1. In this way, the chance that the hot air flows into the cold aisle CA is reduced, such that the heat-dissipation of the servers 120 is correspondingly increased, thus facilitating energy saving and reducing the chance of forming a local hot spot in the chamber.

In general, as shown in FIG. 1, the floor F of the chamber is disposed with an air inlet P. The location of the air inlet P corresponds to the cold aisle CA, so as to provide a cold air to the cold aisle CA. As mentioned above, the space of the cold aisle CA close to the top end 112 is decreased. Thus, the hot air produced during the operation of the servers 120 can be prevented from rising up from the hot aisle HA to the top of the server rack 100 and then flowing towards the cold aisle CA. Therefore, sufficient cold air in the cold aisle CA can be maintained, thus further facilitating energy saving and reducing the chance of forming a local hot spot in the chamber.

From the structural point of view, each of the slide rail structures 130 includes a pair of inner rails 131 and a pair or outer rails 132. The pair of inner rails 131 is respectively connected to two opposite sides of the corresponding server 120. The pair or outer rails 132 is respectively connected to the corresponding pair of inner rails 131 and connected to the frame 110. The corresponding pair of inner rails 131 is slidable relative to the pair of the outer rails 132. Through this simple structure, a user can briefly slide each of the servers 120 out of the frame 110 without using any extra tools. Thus, the user can adjust the size of the spaces of the cold aisle CA and the hot aisle HA conveniently, thereby meeting the heat-dissipation requirements of the servers 120.

Furthermore, each of the slide rail structures 130 further includes a locking portion 133. The locking portion 133 is configured to fix a relative position between the corresponding pair of inner rails 131 and the corresponding pair of outer rails 132. The locking portions 133 may be screws, fixing clips or fasteners of other forms. However, this does not intend to limit the present disclosure.

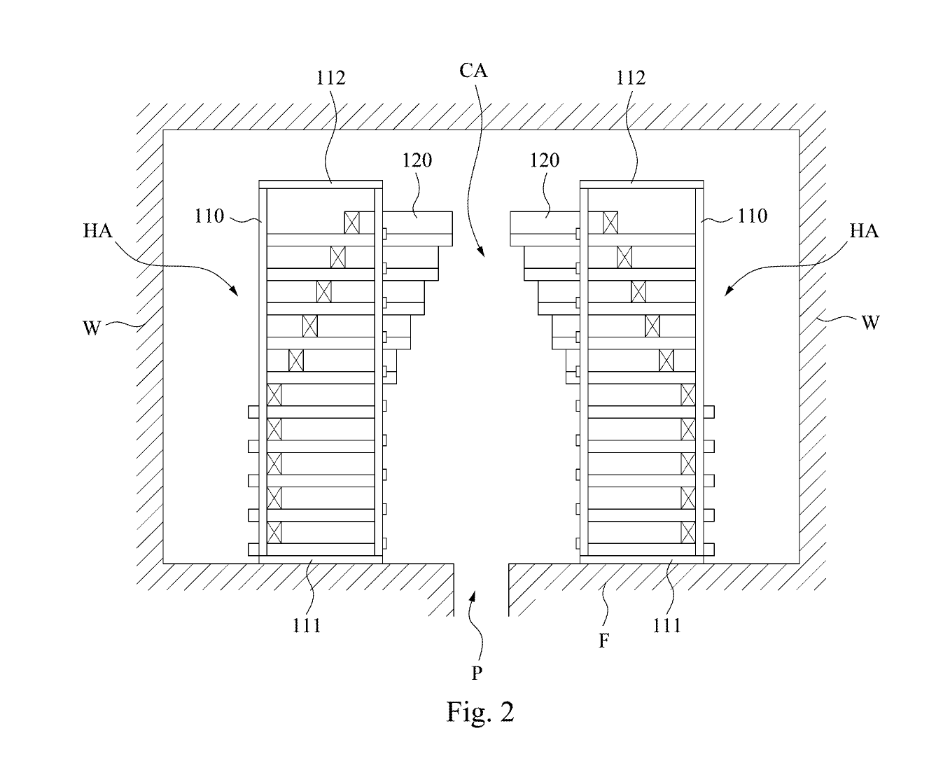

Please refer to FIG. 2. FIG. 2 is a schematic application diagram of a server rack 100 according to another embodiment of the present disclosure. In this embodiment, as shown in FIG. 2, two server racks 100 are disposed with the corresponding operation ends 121 facing each other, such that a cold aisle CA is formed between the two server racks 100, while hot aisles HA are formed respectively between each of the server racks 100 and the adjacent sidewall W. Furthermore, the servers 120 located closer to the top end 112 of the frame 110 slide towards each other, and the distance by which each of the servers 120 slides out of the frame 110 is greater than or equal to the distance by which the adjacent server 120 closer to the bottom end 111 slides out of the frame 110. Therefore, in addition to increasing the space of the hot aisles HA next to the two server racks 100 close to the top end 112 of each of the frames 110 as shown in FIG. 2, the size of the space of the cold aisle CA between the two server racks 100 close to the top ends 112 can also be flexibly adjusted by the user. Thus, the user can meet the heat-dissipation requirements of the servers 120 according to the actual needs.

In sum, when being compared with the prior art, the embodiments of the present disclosure mentioned above have at least the following advantages:
(1) The space of the hot aisle close to the top end is increased to facilitate the hot air produced during the operation of the servers to flow towards a ventilation fan. Consequently, the chance of the hot air flowing into the cold aisle is reduced, such that the heat-dissipation of the servers is correspondingly increased, thus facilitating energy saving and reducing the chance of forming a local hot spot in the chamber.

(2) Since the space of the cold aisle close to the top end is decreased, the hot air produced during the operation of the servers can be prevented from rising up from the hot aisle to the top of the server rack and then flowing towards the cold aisle. Therefore, sufficient cold air in the cold aisle can be maintained, thus further facilitating energy saving and reducing the chance of forming a local hot spot in the chamber.

(3) The pair of inner rails is respectively connected to two opposite sides of the corresponding server, and the pair or outer rails is respectively connected to the corresponding pair of inner rails and connected to the frame. The corresponding pair of inner rails is slidable relative to the pair of the outer rails. Through this simple structure, a user can briefly slide each of the servers out of the frame without using any extra tools. Thus, the user can adjust the size of the spaces of the cold aisle and the hot aisle conveniently, thereby meeting the heat-dissipation requirements of the servers.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. A server rack, comprising:
a frame having a bottom end and a top end opposite to each other;
a plurality of servers stacked between the bottom end and the top end, each of the servers having an operation end and a heat-dissipation end opposite to each other; and
a plurality of slide rail structures connecting the servers to the frame for allowing each of the servers to at least partially slide out of the frame towards the corresponding operation end;
wherein a distance by which each of the servers slides out of the frame is greater than or equal to a distance by which the adjacent server located closer to the bottom end slides out of the frame.

2. The server rack of claim 1, wherein each of the slide rail structures comprises:
a pair of inner rails respectively connected to two opposite sides of the corresponding server; and
a pair or outer rails respectively connected to the corresponding pair of inner rails and connected to the frame, wherein the corresponding pair of inner rails is slidable relative to the pair of the outer rails.

3. The server rack of claim 2, wherein each of the slide rail structures further comprises a locking portion configured to fix a relative position between the corresponding pair of inner rails and the corresponding pair of outer rails.

4. The server rack of claim 1, wherein the servers slide along a first direction.

5. The server rack of claim 4, wherein the servers are arranged along a second direction, and the second direction and the first direction are substantially perpendicular to each other.

6. The server rack of claim 1, wherein each of the servers comprises a fan located at the corresponding heat-dissipation end.
